(19) United States
(12) Patent Application Publication
(10) Pub. No.: US 2007/0052032 A1
(43) Pub. Date: Mar. 8, 2007

(54) Electrostatic discharge device with latch-up immunity

(76) Inventors: Chih-Feng Huang, Jhubei City (TW); Ta-yung Yang, Milpitas, CA (US); Jenn-yu G. Lin, Taipei (TW); Tuo-Hsin Chien, Tucheng City (TW)

Correspondence Address: J C PATENTS, INC., 4 VENTURE, SUITE 250, IRVINE, CA, 92618, US

(21) Appl. No.: 11/223,745

(22) Filed: Sep. 8, 2005

(51) Int. Cl. H01L 23/62

(52) U.S. Cl. 257/357

(57) ABSTRACT

An electrostatic discharge (ESD) device with latch-up immunity is provided. The ESD device has an equivalent SCR structure when a supply voltage is not applied thereto and has an equivalent PN diode structure when the supply voltage is applied thereto, thus freeing the ESD device from the latch-up phenomenon.

### BACKGROUND OF THE INVENTION

1. Field of the Invention

The present invention relates to an electrostatic discharge (ESD) device. More particularly, it relates to an ESD device with a silicon controlled rectifier (SCR) structure and being immune from the latch-up phenomenon.

2. Description of the Related Art

Electrostatic discharge (ESD) devices are widely applied in integrated circuits (IC) to prevent them from being damaged by electrostatic discharges. In general, a latch-up effect happens to the ESD device with a silicon controlled rectifier (SCR) structure due to its congenital limitation. Once the SCR structure is triggered, a great amount of current is carried by the SCR structure, but the voltage crossing over two terminals thereof returns to a low sustained voltage. When the SCR structure is latched after being trigged, the SCR structure cannot return to its normal operating state; thus, the function provided by the ESD device will be no longer available.

Therefore, how to improve the latch-up immunity of the ESD device has become a major subject in designing ESD devices. Accordingly, an ESD device with latch-up immunity is greatly desired by the industry.

### SUMMARY OF THE INVENTION

Accordingly, at least one object of the present invention is to provide latch-up immunity for an ESD device having parasitic SCR structure. To this end the equivalent SCR structure is changed in order to free the ESD device from the latch-up phenomenon whenever it occurs.

To achieve these and other advantages in accordance with the purpose of the invention, as embodied and broadly described herein, the present invention provides an ESD device with latch-up immunity, that comprises a P-type substrate, an N-type well, a first N+ doped region, a first P+ doped region, a second N+ doped region, a second P+ doped region, a third N+ doped region, a third P+ doped region, a first electrode, and a second electrode.

The N-type well is formed in the P-type substrate. The first N+ doped region and the first P+ doped region are formed in the N-type well and isolated from each other by a third field oxide layer. The second N+ doped region is formed between the first P+ doped region and a first field oxide layer. The second N+ doped region is adjacent to the first P+ doped region. The third N+ doped region is formed in the P-type substrate and outside the N-type well; and the third N+ doped region is isolated from the N-type well. The second P+ doped region is formed in the P-type substrate and outside the N-type well; and the second P+ doped region is isolated from the N-type well.

The third P+ doped region is disposed in the P-type substrate and outside the N-type well. The third P+ doped region is isolated from the second N+ doped region by the first field oxide layer. The third P+ doped region is isolated from the third N+ doped region by a fourth field oxide layer; and the third N+ doped region is isolated from the second P+ doped region by a second field oxide layer. In addition, the first electrode is electrically coupled to the second P+ doped region and the third N+ doped region through a first electric conductor, and the second electrode is electrically coupled to the first N+ doped region and the first P+ doped region through a second electric conductor.

In the present invention, the third P+ doped region is disposed in the equivalent SCR structure of the ESD device. The electrostatic discharge occurs when the supply voltage is not applied to the ESD device. The third P+ doped region is in floating status; the ESD device is working as an equivalent SCR structure. A surge occurs when the supply voltage is applied to the ESD device. The third P+ doped region is electrically coupled to a lowest potential through a switch, so that the equivalent SCR structure of the ESD device shifts to an equivalent PN diode structure, and the ESD device is free from the latch-up phenomenon.

### BRIEF DESCRIPTION OF THE DRAWINGS

The accompanying drawings are included to provide a further understanding of the invention, and are incorporated in and constitute a part of this specification. The drawings illustrate embodiments of the invention, and together with the description, serve to explain the principles of the invention.

FIG. 1 schematically shows a sectional view of an ESD device having an equivalent SCR structure according to one embodiment of the present invention.

FIG. 2 schematically shows an equivalent circuit diagram of the ESD device without power voltage applied according to one embodiment of the present invention.

FIG. 3 schematically shows an equivalent circuit diagram of the ESD device with power voltage applied according to one embodiment of the present invention.

### DESCRIPTION OF PREFERRED EMBODIMENTS

Reference will now be made in detail to the present embodiments of the invention, examples of which are illustrated in the accompanying drawings. Wherever possible, the same reference numbers are used in the drawings and the description to refer to the same or like parts.

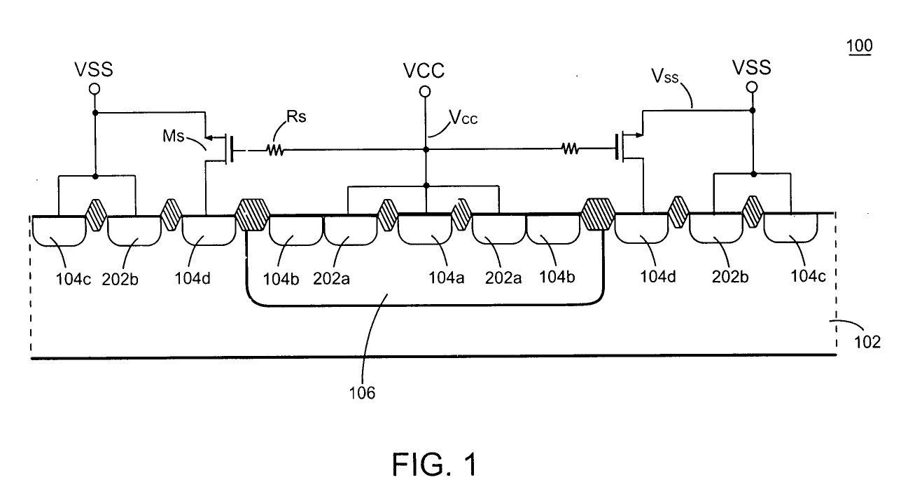

One embodiment below describes how to overcome the disadvantage of the conventional ESD device, and how to achieve the latch-up immunity. FIG. 1 schematically shows a sectional view of an ESD device having an equivalent SCR structure according to one embodiment of the present invention. In FIG. 1, an N-type well 106 is formed in a P-type substrate 102. According to the embodiment of the present invention, a first N+ doped region 104a, a plurality of first P+ doped regions 202a, and a plurality of second N+ doped regions 104b are disposed in the N-type well 106; and a plurality of third N+ doped regions 202b and a plurality of second P+ doped regions 104c are formed outside the N-type well 106 so that the ESD device 100 having the equivalent SCR structure is formed. When the ESD device 100 is triggered by the electrostatic discharge, the connected complement doped regions, such as the N+ doped region 104a and the P+ doped region 202a, operate at different voltage levels.

The equivalent SCR structure of the ESD device 100 comprises two equivalent transistors and two internal resistors. The first P+ doped region 202a, the N-type well 106, and the P-type substrate 102 together form an equivalent PNP transistor; and the N-type well 106, the P-type substrate 102, and the third N+ doped region 202b together form an equivalent NPN transistor.

In the present embodiment, the second P+ doped region 104c and the third N+ doped region 202b outside the N-type well 106 are electrically coupled to a first electrode VSS through a first electric conductor. The second P+ doped region 104c is isolated from the third N+ doped region 202b by a second field oxide layer. In the N-type well 106, the first N+ doped region 104a, a plurality of the first P+ doped regions 202a, and a plurality of the second N+ doped regions 104b alternatively sequentially form a sequence of doped regions. The two terminals at the sequence of doped regions are the second N+ doped regions 104b. Moreover, the first N+ doped region 104a and the first P+ doped region 202a are electrically coupled to a second electrode VCC through a second electric conductor, wherein the first P+ doped region 202a is isolated from the first N+ doped region 104a by a third field oxide layer. The second N+ doped region 104b is adjacent to the first P+ doped region 202a. In addition, the aforesaid first and second electric conductors can be made of metal.

In the present embodiment, a plurality of additional third P+ doped regions 104d can be disposed in the equivalent SCR structure of the ESD device 100, wherein the third P+ doped region 104d is formed in the P-type substrate 102 and outside the N-type well 106. One terminal of the third P+ doped region 104d is isolated from the second N+ doped region 104b by a first field oxide layer, and the other terminal of the third P+ doped region 104d is isolated from the third N+ doped region 202b by a fourth field oxide layer.

In the present embodiment, the ESD device 100 further comprises a switch Ms and a resistor R_{S}. A first terminal of the switch M_{S} and a second terminal of the switch Ms are electrically coupled to the third P+ doped region 104d and the first electrode VSS, respectively, wherein a parasitic capacitor C_{P} congenitally exists between a control terminal and the second terminal of the switch Ms. Moreover, two terminals of the resistor R_{S} are electrically coupled to the control terminal of the switch M_{S} and the second electrode VCC, respectively.

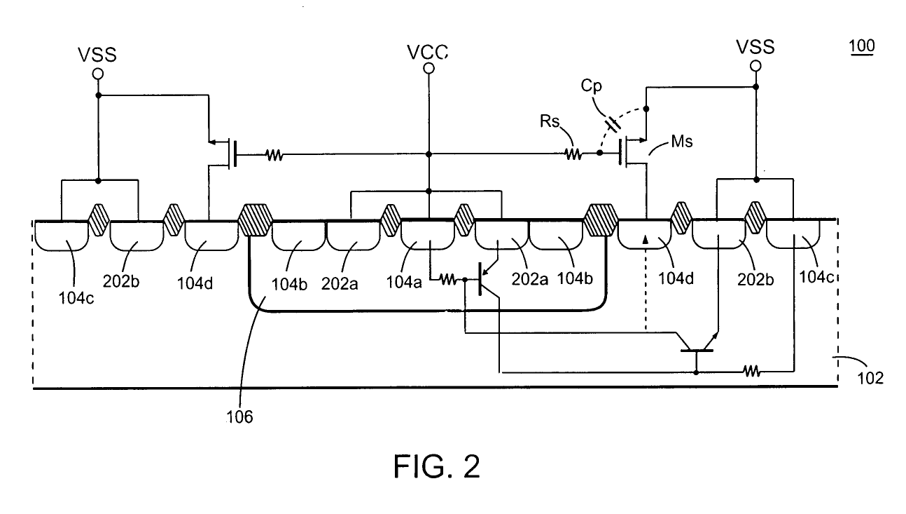

FIG. 2 schematically shows an equivalent circuit diagram of the ESD device 100 without supply voltage applied according to one embodiment of the present invention. The electrostatic discharge occurs when the supply voltage is not applied to the ESD device 100; meanwhile, since there is no gate voltage the switch M_{S} is turned off so that the third P+ doped region 104d is floating connected. Accordingly, the first P+ doped region 202a, the N-type well 106, the P-type substrate 102, and the third N+ doped region 202b together form the equivalent SCR structure. When the electrostatic discharge is conducted to the second electrode VCC, since the duration of the electrostatic discharge is very short and the charging of the parasitic capacitor C_{P} of the switch Ms is delayed, the switch M_{S} remains in an off state during the electrostatic discharge. Therefore, the equivalent SCR of the ESD device 100 is turned on, triggered by the electrostatic discharge so that a great amount of the electrostatic discharge is conducted to the first electrode VSS from the second electrode VCC. When the electrostatic discharge is completed, since the supply voltage is not applied to the ESD device 100, the electrostatic current is smaller than its holding current. Therefore, the equivalent SCR is immune from the latch-up occurrence

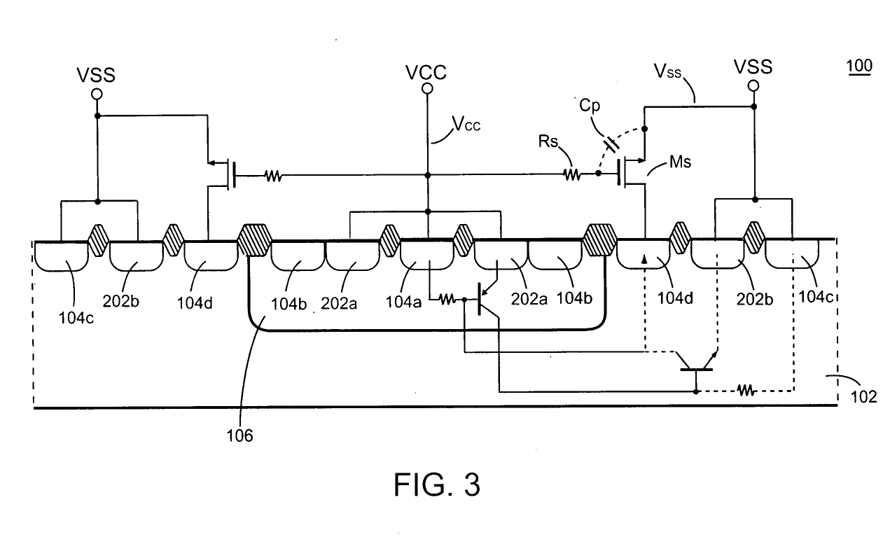

FIG. 3 schematically shows an equivalent circuit diagram of the ESD device 100 with the supply voltage applied according to one embodiment of the present invention. Here, for example, the first electrode VSS is electrically coupled to a lowest potential (or a ground potential) V_{SS}, and the second electrode VCC is electrically coupled to a highest potential (or a supply voltage) V_{CC}. When the ESD device 100 is powered, the highest potential (or the supply voltage) V_{CC} charges the parasitic capacitor C_{P} of the switch Ms through the resistor R_{S}; then, the switch M_{S} is turned on when the charging is completed. Therefore, the third P+ doped region 104d is electrically coupled to the lowest potential (or the ground potential) V_{SS}. Meanwhile, since the third P+ doped region 104d is electrically coupled to the lowest potential, the equivalent NPN transistor formed by the N-type well 106, the P-type substrate 102, and the third N+ doped region 202b in the equivalent SCR structure of the ESD device 100 is disabled, and meanwhile only one equivalent PN diode formed by the third P+ doped region 104d and the first N+ doped region 104a is used to effectively free the ESD device 100 from latch-up when the surge is conducted to the second electrode VCC.

In summary, whether the supply voltage is applied or not, the ESD device 100 provided by the present invention can effectively avoid the latch-up phenomenon to improve the performance of the ESD device 100.

Although the invention has been described with reference to a particular embodiment, it will be apparent to one of the ordinary skill in the art that modifications to the described embodiment may be made without departing from the spirit of the invention. Accordingly, the scope of the invention will be defined by the attached claims not by the above detailed description.

What is claimed is:

1. An electrostatic discharge (ESD) device with latch-up immunity, comprising:
a P-type substrate;
an N-type well, formed in said P-type substrate;
a first N+ doped region, formed in said N-type well;
a first P+ doped region, formed in said N-type well;
a second N+ doped region, formed between said first P+ doped region and a first field oxide layer;
a third N+ doped region, formed in said P-type substrate and outside said N-type well, wherein said third N+ doped region is isolated from said N-type well;
a second P+ doped region, formed in said P-type substrate and outside said N-type well, wherein said second P+ doped region is isolated from said N-type well;
a first electrode, electrically coupled to said second P+ doped region and said third N+ doped region through a first electric conductor;
a second electrode, electrically coupled to said first N+ doped region and said first P+ doped region through a second electric conductor; and
a third P+ doped region, formed in said P-type substrate and outside said N-type well, wherein said third P+ doped region is isolated from said second N+ doped region by said first field oxide layer, when a supply voltage is not applied to the ESD device, said third P+ doped region is floating connected, and when said supply voltage is applied to said ESD device, said third P+ doped region is electrically coupled to a lowest potential.

2. The ESD device of claim 1, wherein said second P+ doped region is isolated from said third N+ doped region by a second field oxide layer.

3. The ESD device of claim 1, wherein said first P+ doped region is isolated from said first N+ doped region by a third field oxide layer.

4. The ESD device of claim 1, wherein said third N+ doped region is isolated from said third P+ doped region by a fourth field oxide layer.

5. The ESD device of claim 1, wherein said first electrode is electrically coupled to said lowest potential.

6. The ESD device of claim 5, further comprising:
a switch, having a first terminal and a second terminal electrically coupled to said third P+ doped region and said first electrode respectively, wherein said switch has a parasitic capacitor located between a control terminal of said switch and said second terminal of said switch; and
a resistor, having a first terminal and a second terminal electrically coupled to said control terminal of said switch and said second electrode, respectively.

7. The ESD device of claim 6, wherein when said supply voltage is applied to said ESD device, said switch is turned on so that said third P+ doped region is electrically coupled to said lowest potential through said switch.

8. The ESD device of claim 1, wherein said first electric conductor and said second electric conductor are made of metal.

9. The ESD device of claim 1, wherein said first P+ doped region is adjacent to said second N+ doped region.
